(19) United States
(12) Patent Application Publication
(10) Pub. No.: US 2023/0087777 A1
(43) Pub. Date: Mar. 23, 2023

(54) MACHINE LEARNING SYSTEM DESIGNS FOR PATTERNING MODELS WITH ONLINE AND/OR DECENTRALIZED DATA

(71) Applicant: International Business Machines Corporation, Armonk, NY (US)

(72) Inventors: Jing Sha, White Plains, NY (US); Martin Burkhardt, White Plains, NY (US); NELSON FELIX, Slingerlands, NY (US)

(21) Appl. No.: 17/480,076

(22) Filed: Sep. 20, 2021

(51) Int. Cl. G06N 3/04

(52) U.S. Cl. CPC G06N 3/0454

(57) ABSTRACT

To increase the efficiency of electronic design automation, employ a first subset of integrated circuit patterning modeling data to generate weights of a neural network-based patterning model; employ a second subset of integrated circuit patterning modeling data to generate updated weights of the neural network-based patterning model, to obtain an updated neural network-based patterning model; evaluate the updated neural network-based patterning model; and responsive to the evaluating of the updated neural network-based patterning model being successfully completed, deploy the updated neural network-based patterning model.

### BACKGROUND

The present invention relates to the electrical, electronic, and computer arts, and more specifically, to the application of machine learning (ML) to semiconductor Electronic Design Automation (EDA) and the like.

In VLSI (very large-scale integration) digital design, fabricated devices conventionally include millions of transistors implementing hundreds of storage devices, functional logic circuits, and the like. EDA involves the use of software tools for designing electronic systems such as integrated circuits (ICs) (e.g., VLSI circuits) and printed circuit boards. The designs are often segmented or partitioned into sub-blocks (such as cores, units, macros, sub-hierarchies, and the like) to make the design process more manageable.

In the process of fabricating integrated circuits, patterning refers to the process of using photolithography and optical masks to print patterns that guide the deposition of material on/removal of material from the wafer during fabrication. At each layer of the device, material is deposited/removed in the areas not covered by the mask. The wafer is repeatedly processed in this fashion (typically with a new mask at each layer), creating multiple layers of circuitry.

Machine learning systems have been employed for patterning models in the field of EDA. Most of the work in the field of machine learning (or specifically deep learning) for patterning is focused on specific models or training techniques.

As used herein, online data is basically data generated on the fly or sequentially, and decentralized data is data that is not generated at a single or centralized location/machine.

### SUMMARY

Principles of the invention provide techniques for machine learning system designs for patterning models with online and/or decentralized data. In one aspect, an exemplary method for increasing the efficiency of electronic design automation includes employing a first subset of integrated circuit patterning modeling data to generate weights of a neural network-based patterning model; employing a second subset of integrated circuit patterning modeling data to generate updated weights of the neural network-based patterning model, to obtain an updated neural network-based patterning model; evaluating the updated neural network-based patterning model; and responsive to the evaluating of the updated neural network-based patterning model being successfully completed, deploying the updated neural network-based patterning model.

In another aspect, another exemplary method for increasing the efficiency of electronic design automation includes distributing an initial neural network-based patterning model from a server to a plurality of clients; receiving, at the server, from the plurality of clients, a plurality of model weight updates prepared by each of the clients based on the initial neural network-based patterning model and a plurality of sets of local modeling data; the server aggregating the plurality of model weight updates to obtain a combined neural network-based patterning model; deploying the combined neural network-based patterning model; and refraining from communication between the clients and refraining from allowing any of the local modeling data to leave the clients.

An exemplary computer includes a memory; and at least one processor, coupled to the memory, and operative to increase the efficiency of electronic design automation by implementing part or all of any of the disclosed methods.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor, by sending appropriate data or commands to cause or aid the action to be performed. For the avoidance of doubt, where an actor facilitates an action by other than performing the action, the action is nevertheless performed by some entity or combination of entities.

One or more embodiments of the invention or elements thereof can be implemented in the form of a computer program product including a computer readable storage medium with computer usable program code for performing the method steps indicated. Furthermore, one or more embodiments of the invention or elements thereof can be implemented in the form of a system (or apparatus) including a memory, and at least one processor that is coupled to the memory and operative to perform exemplary method steps. Yet further, in another aspect, one or more embodiments of the invention or elements thereof can be implemented in the form of means for carrying out one or more of the method steps described herein; the means can include (i) hardware module(s), (ii) software module(s) stored in a computer readable storage medium (or multiple such media) and implemented on a hardware processor, or (iii) a combination of (i) and (ii); any of (i)-(iii) implement the specific techniques set forth herein.

Techniques of the present invention can provide substantial beneficial technical effects. Some embodiments may not have these potential advantages and these potential advantages are not necessarily required of all embodiments. For example, one or more embodiments provide one or more of:

improve the technological process of designing integrated circuits by enhancing patterning model robustness (model updates itself with new wafer data to improve accuracy and generalization);

improve the technological process of designing integrated circuits by enhancing efficiency (model update time is dependent on the size of new wafer data (no need to re-train with old wafer data) and there is no need to store old training data);

improve the technological process of designing integrated circuits by enhancing capability to evolve (the model stays relevant to the latest masks);

improve the technological process of designing integrated circuits by enhancing scalability (ability to support both data parallelism and model parallelism);

for fixed computer resources, improve the quality of an integrated circuit design as compared to a circuit design using prior art techniques;

enable collaborative training of shared machine learning-based models while all the training data stays locally on different machines and/or different geographic locations (for example, enhancing data security in cases of collaboration).

These and other features and advantages of the present invention will become apparent from the following detailed description of illustrative embodiments thereof, which is to be read in connection with the accompanying drawings.

### BRIEF DESCRIPTION OF THE DRAWINGS

FIGS. 1-5 are sequential data flow and block diagrams depicting a first technique for machine-learning-based IC patterning models, according to an aspect of the invention;

FIGS. 6-10 are sequential data flow and block diagrams depicting a second technique for machine-learning-based IC patterning models, according to an aspect of the invention;

FIG. 11 depicts a computer system that may be useful in implementing one or more aspects and/or elements of the invention;

FIG. 12 is a flow diagram of a design process used in semiconductor design, manufacture, and/or test;

FIG. 13 shows further aspects of IC fabrication from physical design data; and FIG. 14 shows an exemplary high-level Electronic Design Automation (EDA) tool flow, within which aspects of the invention can be employed.

### DETAILED DESCRIPTION

One or more embodiments address machine learning system designs for patterning models. As noted, most of the work in the field of machine learning (or specifically deep learning) for patterning is focused on specific models or training techniques, while one or more embodiments are independent of model type or architecture. One or more embodiments advantageously address how to build models more efficiently by using training data collected at different time(s) and/or location(s).

Heretofore, modeling data has been collected and fed at once into an ML model for training. In comparison, one or more embodiments include multiple extra steps between the modeling data and the model. Furthermore, in one or more embodiments, the modeling data is not a single chunk, but rather is broken into multiple smaller chunks which are more realistic and also have many advantages as discussed elsewhere herein.

A conventional model flow typically includes the generation of training and testing data, the training of a deep neural network-based model, and the fine tuning of the hyperparameters of the deep neural network-based model. In a non-limiting exemplary embodiment, an additional step, after the generation of the training and testing data, and prior to training, includes locally evaluating updates from a shared mode. Furthermore, in this non-limiting exemplary embodiment, additional steps, after the training step and prior to the fine-tuning step, include evaluating the new model for update with online data; updating the model with neural network weight updates; and client machines sending the model updates to a server for aggregation. Thus, pertinent steps involve, for example, data analysis, model evaluation, model update, and model weight aggregation (privacy-preserving aggregation for decentralized data is pertinent in one or more embodiments). Please note that other embodiments can us a different ordering of steps.

One or more embodiments apply to any layer (i.e. wiring layers in an integrated circuit), any technology node (e.g., 10 nm, 7 nm, and beyond), and/or neural network-based models of any neural network model architectures or hyperparameters. A pertinent high-value attribute of one or more embodiments is that the methods cover any neural network-based models (including those now provided in EDA tools) and make the models capable of handling large amounts of data (i.e., so large that it is impractical to train on all the data at once) for training (and/or data generated at different times and/or locations), which otherwise is not available due to all sorts of limitations, such as metrology resources, design space coverage of masks, and the like. Also, one or more embodiments include techniques implementing online learning (i.e., training data on the fly) and/or federated learning (i.e., collaboratively learning a shared model while keeping all the training data local).

One or more embodiments thus provide techniques for building and updating deep neural network-based patterning models with batches of training data collected or transferred at different times without requiring retraining the entire dataset from scratch. Furthermore, one or more embodiments provide techniques for collaboratively training shared deep neural network-based patterning models while all the training data stays locally on different machines and/or at different geographic locations. Advantageously, one or more embodiments apply to any layer and/or any technology node where deep neural network-based patterning models are used. Deep neural network-based models can have different architectures and/or hyperparameters in one or more embodiments.

A patterning model is typically built by tuning model parameters in order to match simulation results to wafer data. More wafer data usually makes a model more robust and better able to generalize; however, data collection is expensive and limited by metrology resources, design/mask, etc. Wafer data on new masks, outside the coverage of the original model, needs to be used to update the model. Current solutions to modeling a frozen patterning process include:

model build and verification done once, for specific mask(s), which only covers a small subset of all design patterns on the mask(s);

model build once and verification done multiple times (for different mask(s), in which model verification data is not used to “update”/refit the model along with model build data; and

both solutions, in which predetermined patterns are inspected repeatedly for all wafers with the mask for process control, while no wafer data is collected on uninspected patterns after model build and verification.

More wafer data usually makes a patterning model more robust and better able to generalize. However, data collection may not finish at a single time or location, due to limitations of metrology resources, design space coverage on a specific mask, and so on. Any new wafer data, especially if not covered by the original model, typically should be included to update the model and make it more robust and relevant. One of the current solutions to modeling a frozen patterning process is to carry out model build and verification once and for all. This approach usually just covers a small subset of all the design patterns on a single mask for both model build and model verification. Another solution is building the model once on a mask and doing verification multiple times on different masks. This is also a common practice, but a disadvantage to this approach is that model verification data is not used to update the model, especially when the modeling errors are not negligible. In this case, new wafer data is wasted and a model stays stale. Both solutions may share the disadvantage that no new wafer data is collected and used after a model is built.

Advantageously, one or more embodiments provide machine learning system designs for patterning models with online and/or decentralized data. In one or more embodiments, a Deep Neural Network (DNN)-based patterning model is constantly updated with online and/or decentralized wafer data to achieve better model performance without concerns of metrology capacity, data transfer/storage, or privacy. The model building strategies are applicable, for example, to any machine learning models using stochastic gradient descent and backpropagation for optimization. Advantages include robustness (model updates itself with new wafer data to improve accuracy and generalization); efficiency (model update time is dependent on the size of new wafer data (no need to re-train with old wafer data) and there is no need to store old training data); capability to evolve (the model stays relevant to the latest masks); scalability (ability to support both data parallelism and model parallelism); and/or collaboratively learning a shared model while ensuring privacy.

In one or more embodiments, deep neural network-based patterning models can be updated with online and/or decentralized data, without re-training with all the data from scratch. One or more embodiments are not limited by metrology capacity, data transfer and storage limitations, or privacy concerns, which current approaches cannot avoid. An advantage of one or more embodiments includes improved robustness of the model, which usually achieves better accuracy and generalization with more training data. Another advantage is that it takes less time to update a model without the need to retrain with all the data. Also, in one or more embodiments there is no need to store old and less relevant training data which is already accounted for by weights of neural network-based models. As the model keeps updating itself with new wafer data, it typically always stays relevant to the latest masks. As will be appreciated by the skilled artisan familiar with network-based models, scalability is an advantage for almost all neural network-based models that support both data parallelism and model parallelism.

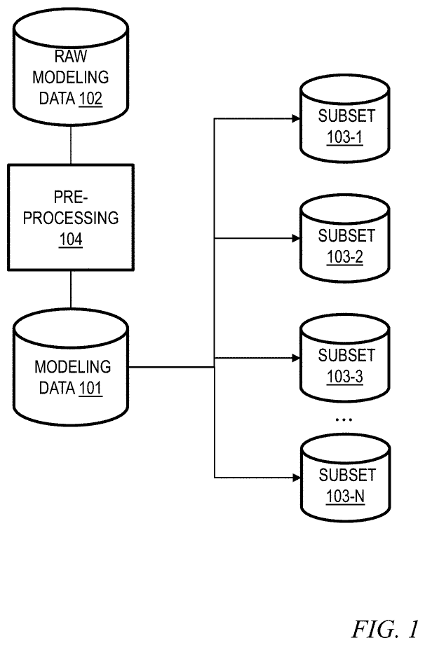

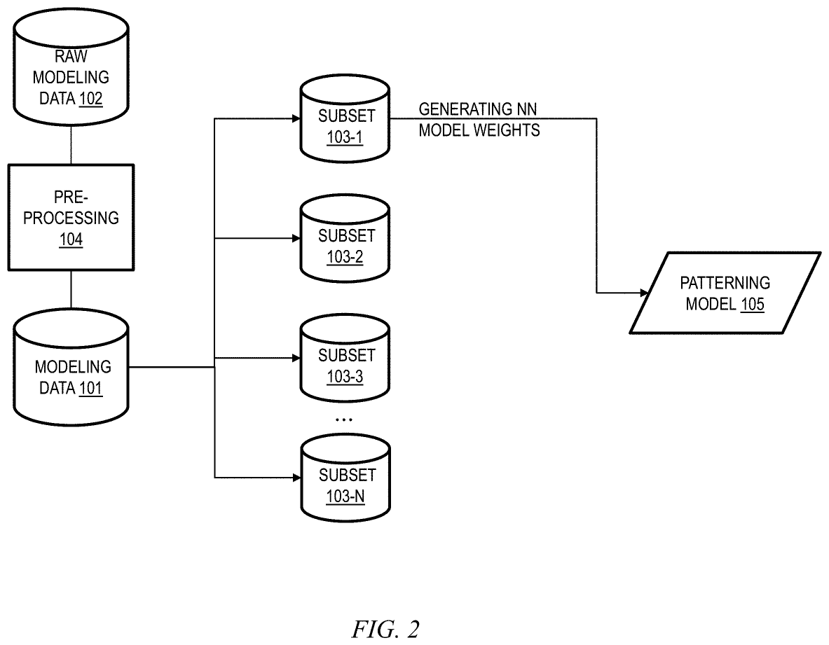

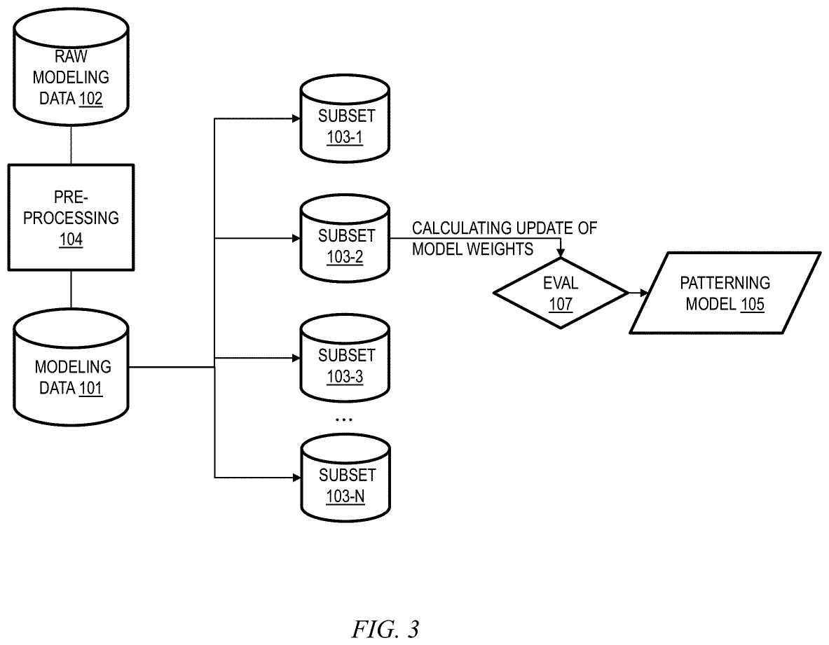

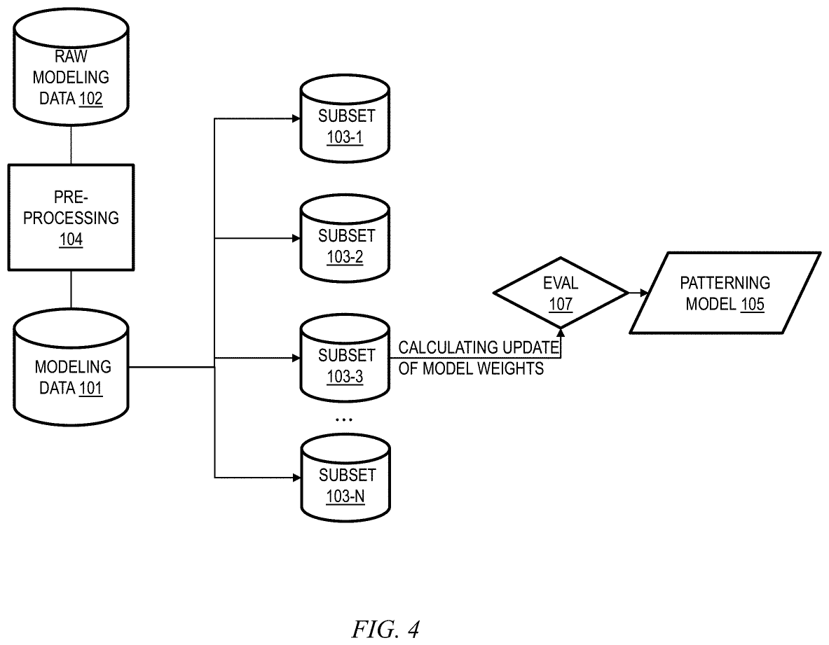

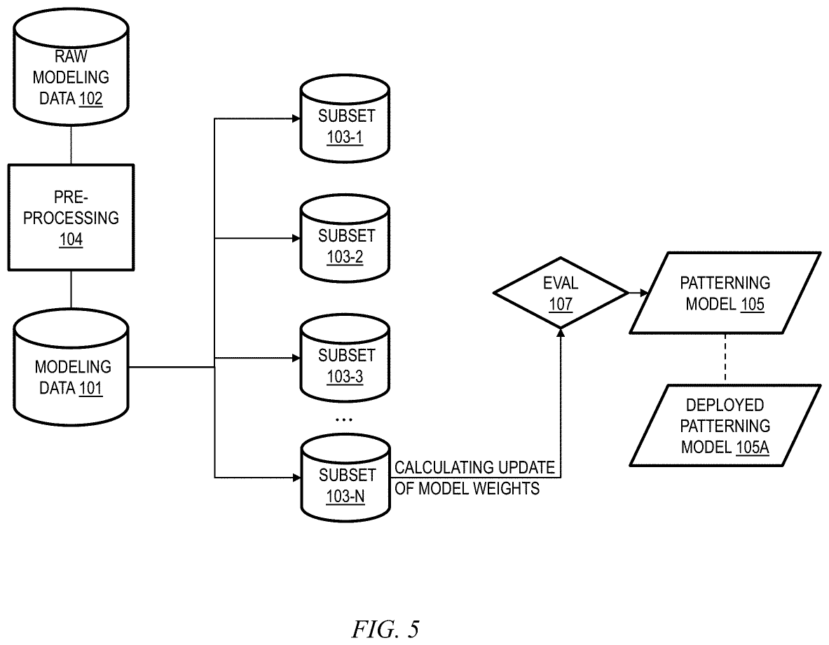

Referring now to FIG. 1, an exemplary workflow for online data will be described. Modeling data 101 can be, for example, a huge data set collected over time or a constant data stream. Note first through N^{th} data subsets 103-1, 103-2, 103-3, . . . , 103-N. In FIG. 2, the first data subset 103-1 is used to generate weights of a neural network-based patterning model 105. There are known techniques for simulating lithography with convolutional neural networks and for modeling etch bias with machine learning; given the teachings herein, the skilled artisan will be able to adapt such known techniques to generate weights and the like. With attention to FIG. 3, after the initial model build, any future data is used to update the model, or, more specifically, the model weights. Model weight updates are calculated by backpropagation, a widely used algorithm in training neural networks. The amount of importance to place on a specific data subset, also known as learning rate, is tunable. Furthermore in this regard, the learning rate can be higher if the engineer desires the model to have a better fit to the new data. In some instances, it may be desirable for some critical patterns to always fit better than the rest, for a certain model. In such instances, it will be appropriate to evaluate whether a new model can still fit those critical patterns. If the learning rate is too large or too small, critical patterns may not fit properly when using the new model. A suitable evaluation step can be implemented, and if appropriate, the learning rate can be changed. That is to say, the learning rate can be iteratively adjusted based on the evaluation step. If overweighting for new data results in a critical pattern not fitting, overweight can be reduced. Test cases can be run on both the old and the new models, to ensure that the new model handles critical patterns correctly before the new model is deployed. In general, critical patterns can be located in the old dataset or the new dataset, so in some instances, it might be determined that the new data was not sufficiently overweighted because critical patterns in the new data were not met. Thus, additional overweight is needed. Given the teachings herein, the skilled artisan will be able to run appropriate test cases on critical patterns using trained models. For example, feed in critical feature data to both the old and new models and compare the results. In one or more embodiments, as seen at 107, there is an evaluation step between calculating the update of the model weights with new training data and actually launching the updated model. This step ensures that the update of the model weights will not affect the modeling accuracy of critical patterns, while taking into account new data. FIGS. 4 and 5 show how the model keeps getting updated with new data (in FIG. 4, from data subset 103-3, and in FIG. 5, from data subset 103-N). FIG. 5 designates the deployed model (after successful evaluation) as 105A.

Consider some exemplary use cases for the online learning workflow:

when the whole training data set is too large and data collection cannot be completed at one time (subsets are collected and fed into the model for updating);

when a model's (e.g., legacy model's) original training data is lost and it is not desired to train a new model from scratch with both old sampling plans and new sampling plans;

when new training data comes from new masks (it is typically appropriate that the model needs to stay more relevant to these new masks). This can be achieved by a larger learning rate for the new data.

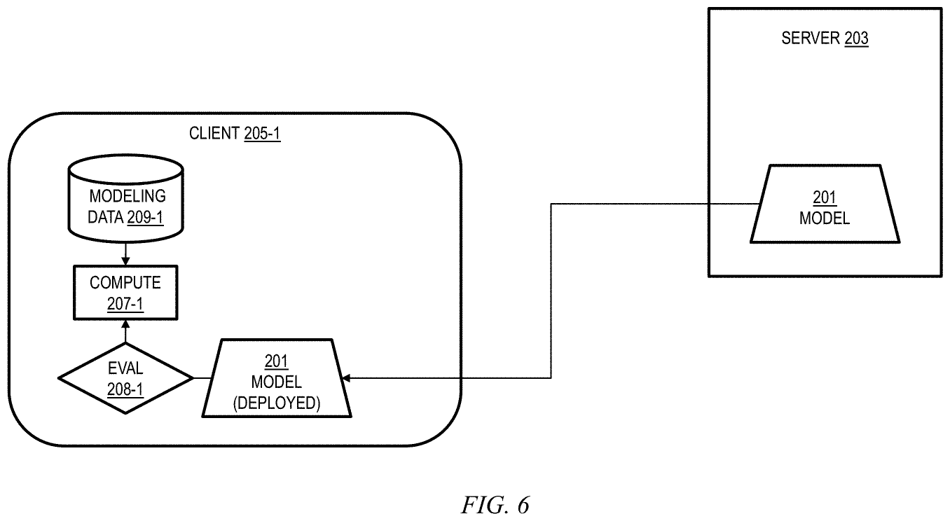

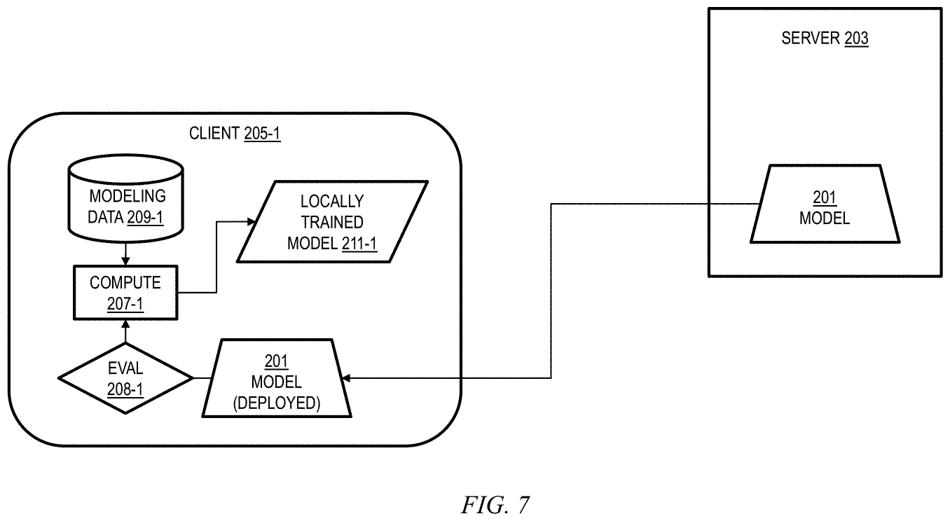

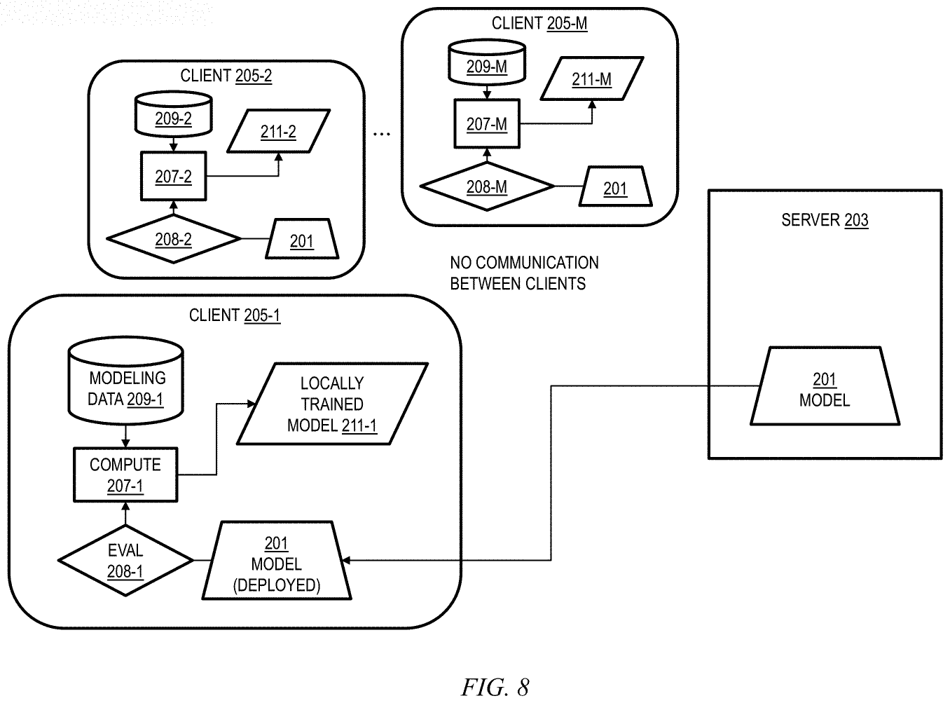

Refer now to FIG. 6 and consider a workflow for decentralized data. A model 201 on server 203 is distributed or deployed to one or more clients such as client 205-1. The client trains the model 201 at 207-1 with its own local data 209-1 and produces a new model 211-1 as seen in FIG. 7. Referring to FIG. 8, the process is repeated for additional clients 205-2 . . . 205-M. The corresponding training is shown at 207-2, 207-M; the corresponding local data at 209-2, 209-M; and the corresponding locally trained models at 211-2, 211-M. In the depicted embodiment, no local data leaves any clients 205-1, 205-2, . . . , 205-M and there is no communication between clients.

Consider now the local evaluation “Eval” steps 208-1, 208-2, . . . , 208-M. Evaluation can be carried out as appropriate; for example, in a manner similar to that described for the embodiment of FIGS. 1-5. Each local machine 205-1, 205-2, . . . , 205-M can train its own version of the model. The local machine retains its own version. The server 203 aggregates all the weight updates and generates a new model. The local machine compares the updated model with the local model. If the updated model cannot fit the specific critical features better, then it is not accepted. This is done iteratively as each updated version of the centralized model is distributed to the clients.]

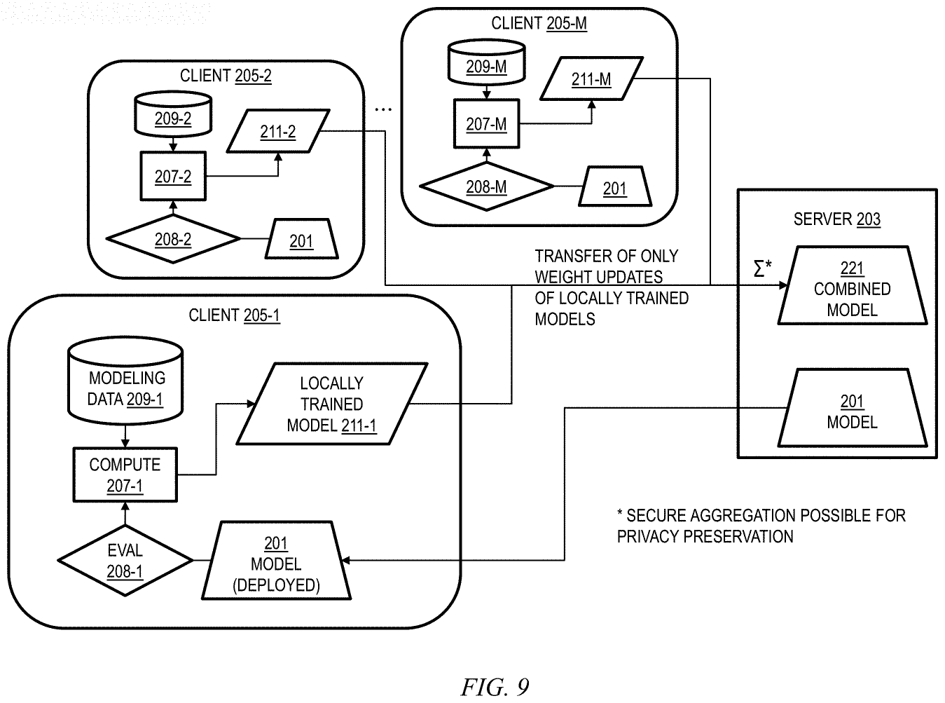

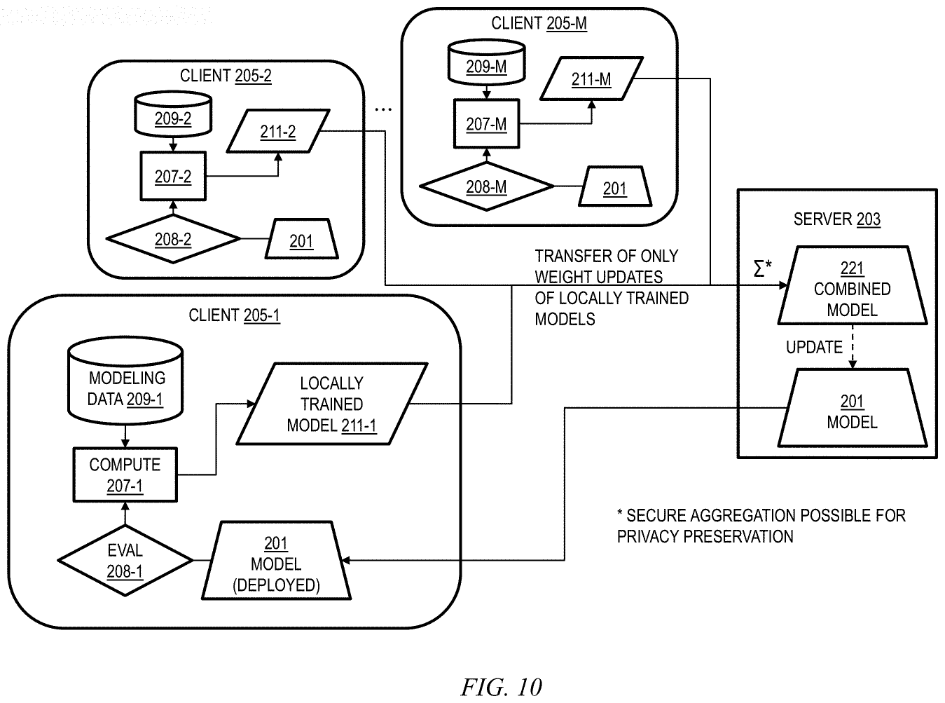

Turning now to FIG. 9, after training with local data 209-1, 209-2, . . . , 209-M, the clients 205-1, 205-2, . . . , 205-M send model weight updates to the server 203, which performs aggregation to generate a combined model 221. The weight aggregation can adapt a secure aggregation protocol that uses cryptographic techniques, which means the server 203 does not know which model updates are from which client. Referring to FIG. 10, the combined model 221 then becomes the initial model 201 for the next iteration and the federated learning process is repeated. The clients 205-1, 205-2, . . . , 205-M and server 203 should be broadly understood as terms to differentiate where local models and centralized models are stored. A client can be a location such as a fabricator, a research and development (R&D) laboratory, or a production line. A client can also be a mask for a specific customer (i.e., not a different physical location but rather a model of a specific mask that it is desired to use for training without sharing the proprietary details of that mask—e.g., a fabricator/foundry has multiple clients with their own masks, the foundry's process is the same for all masks, but it is not desired to share the design details for different masks). This means that customers can share the benefit of a better model by contributing more training data while preserving privacy of their masks. Thus, in one or more embodiments, different fabricators having a “copy-exact” patterning process (“distributed manufacturing”) share the same model but not data, and masks with different design patterns contribute data to a model while preserving their privacy.

Referring back to FIGS. 1-5, one or more embodiments thus provide techniques for building and/or updating a deep neural network-based patterning model with batches of training data 103-1, 103-2, 103-3, . . . , 103-N collected and/or transferred at different times, without the need for re-training with the whole dataset. One or more embodiments include preprocessing (block 104) raw training data 102 as it comes in (i.e., performing data cleaning, analyzing data distribution, etc. in a manner that will be apparent to the skilled artisan); feeding preprocessed training data 101 to an existing patterning model 105; evaluating the new model for update before proceeding; updating the neural network weights of the existing patterning model with weight changes based on the training data; and replacing the existing model with the updated model 105A. Optionally, analyze the accuracy and generalization of deep neural network-based (centralized) models.

Referring back to FIGS. 6-10, in another aspect, one or more embodiments provide techniques for collaboratively training a shared deep neural network-based patterning model 201 while all the training data stays locally on different machines and/or at different geographic locations (generally, clients 205-1, 205-2, . . . , 205-M). One or more embodiments include a server 203 pushing a current model 201 to clients 205-1, 205-2, . . . , 205-M, or clients 205-1, 205-2, . . . , 205-M downloading the current model 201 from the server 203; clients evaluating an update from a shared mode on the server before proceeding; clients training the local model with local data 209-1, 209-2, 209-M; clients summarizing changes of neural network weights as a model update; clients sending model updates to the server (using encrypted communication); and the server averaging all model updates from the clients and updating the centralized model to obtain combined model 221. Optionally, analyze the accuracy and generalization of deep neural network-based (centralized) models.

Given the discussion thus far, and referring, for example, to the embodiment of FIG. 1-5, it will be appreciated that an exemplary method for increasing the efficiency of electronic design automation, according to an aspect of the invention, includes employing a first subset 103-1 of integrated circuit patterning modeling data to generate weights of a neural network-based patterning model 105. A further step includes employing a second subset 103-2 of integrated circuit patterning modeling data to generate updated weights of the neural network-based patterning model, to obtain an updated neural network-based patterning model (which if acceptable will eventually be deployed as seen at 105A). Still a further step includes, at decision block 107, evaluating the updated neural network-based patterning model. A still further step includes, responsive to the evaluating of the updated neural network-based patterning model being successfully completed (Acceptable result from block 107), deploying the updated neural network-based patterning model at 105A.

Patterning can then be carried out with the updated neural network-based patterning model. For example, generate lithography masks based on the updated neural network-based patterning model, and then fabricate an integrated circuit using the lithography masks.

It is worth noting that patterning data is unique in that there are usually critical patterns for which it is most important to ensure a good fit. These critical patterns may shift from previous time periods and/or from previous data sets, depending, for example, on how the design evolves with the “frozen” process. The evaluation step is quite pertinent for patterning models. Due to practical limitations on metrology, patterning data typically cannot be collected all at once, or it may take a significant amount of metrology time. In general, a large amount of training data is desirable; however, there are limits based on metrology tool time. One or more embodiments address this issue using model training by “chunks” of data to improve model accuracy while maintaining performance on critical patterns (i.e., to ensure that such patterns print well).

One or more embodiments can include an additional step or steps of gathering data with metrology tools and storing same in one or more data stores.

The patterning data is for lithography, so it typically includes the critical dimension; the physical dimensions on the wafer after the process. The skilled artisan will be familiar with the concept of Critical Dimension (CD) as the size (width) of a feature printed in photo resist, measured at a specific height above the substrate (also called the linewidth or feature width). Initially, for lithographic patterning, the wafer CD can be simulated with the photomask CD. It is known what was printed on the photomask. During lithography, light passes through the photomask and onto the wafer, which results in obtaining patterned photoresist on the wafer.

For example, the dimensions of the photoresist can be measured, including, for example, but not limited to: CDs (critical dimensions), x and y, width and length. A model is fit to the critical dimensions. Inputs to the model can include, for example, light conditions, polarization, intensity, wavelength, mask dimensions/characteristics (e.g. some masks may have sharper edges than others), and the like. For each pattern, the mask size and shape are initially available. Outputs from the model can include, for example, critical dimensions of the photoresist. Essentially, modeling is carried out based on light and mask characteristics, to infer what the result will be in the photoresist. This is the lithographic patterning model. It is also possible to construct an etch patterning model, comparing the post-lithographic CD to the post-etch CD. Modeling can thus be carried out to correlate light/mask characteristics to the resist result and/or to correlate the patterned resist, etchant, and time to features on the physical chip after etching. Deposition typically does not require modeling, so modeling can. for example, be limited to etching with pertinent etching parameters as input. The etched chip may exhibit a smaller or larger CD as compared to the lithography (for example, the etchant may etch straight down or may also have a sideways etching effect). The skilled artisan will be familiar with training machine learning with a corpus of training data and then evaluating the performance with a test data corpus.

It is worth noting that in any embodiments, when evaluation is not successfully completed, it is possible to refrain from deploying the updated model until it is adjusted and the evaluation successfully completed, as described elsewhere herein (i.e., to ensure that the model weight update will not affect modeling accuracy of critical patterns while taking into account new data).

Suitable hardware and software tools can be used to implement the exemplary method steps. Known metrology tools can be used to collect the data. A general-purpose computer can carry out data cleaning/data preprocessing, using techniques apparent to the skilled artisan, given the teachings herein. For model training, local and/or cloud-based central processing units (CPUs) and or graphical processing units (GPUs) can be employed. Various known hardware acceleration techniques can be used if desired. Inferencing with the trained model can also be carried out with CPUs/GPUs/hardware acceleration techniques. Advantageously, since one or more embodiments use neural-network based models, so-called “black box” proprietary EDA tools are not needed. Open source deep-learning frameworks such as “Tensor Flow” and PyTorch” can be employed if desired.

In one or more embodiments, for evaluation, collect data for critical patterns via metrology. Undertake a comparison with a predetermined metric; for example, Delta CD should not be larger than a certain number. “Deployment” refers to releasing for production or sending a model/result over a network so it can be used (one or more embodiments proceed by permitting authorized parties to access a centralized model). “Carrying out patterning” refers to generating lithography masks and ultimately fabricating a circuit.

As noted, employing the second subset of the integrated circuit patterning modeling data to generate the updated weights of the neural network-based patterning model can include using back-propagation.

Some embodiments include segmenting a pre-existing (typically verge large to the point of being unwieldy) dataset to obtain the first and second subsets.

It is worth noting that one non-limiting exemplary use case of model training of online data is when a model's original training data is lost and it is not desired to train a new model from scratch with both old sampling plans and new sampling plans. For example, typically, old training data is not accessed unless it includes critical features. There might be a legacy model trained on lost data. It may be desirable to use the same process, and so to use the same model, but it is desired to fine-tune it using new data. In this case, even if the old training data is lost, it is still possible to use and/or update the model.

Some instances include collecting the first subset from a data stream at a first time and collecting the second subset from the data stream at a second time, later than the first time. In general, modeling data could be a constant data stream, new training data can come from new test sites, and the like. Optionally, apply a larger learning rate to the second subset as compared to the first subset when generating the updated weights (a larger learning rate can be applied if the model needs to stay more relevant to the new data). An evaluation step can be implemented between calculating the model weights update with the new training data and actually launching the updated model. This step ensures that the model weights update won't affect modeling accuracy of critical patterns while taking into account new data. Picking a larger/smaller learning rate can be done heuristically by a person familiar with machine learning, adjusting the rate to ensure that critical patterns are still met after, e.g., overweight of new data.

It will be appreciated that one or more embodiments are independent of model type or architecture. One or more embodiments are advantageously employed with neural network/machine learning models, using stochastic gradient descent and back-propagation for the model fitting process, allowing determination of the weights to be adjusted. In one or more embodiments, deep neural network-based patterning models can be updated with online and/or decentralized data, without re-training with all the data from scratch.

Furthermore, given the discussion thus far, and referring, for example, to the embodiment of FIG. 6-10, it will be appreciated that an exemplary method for increasing the efficiency of electronic design automation, according to an aspect of the invention, includes distributing an initial neural network-based patterning model 201 from a server 203 to a plurality of clients 205-1, 205-2, . . . , 205-M; and receiving, at the server 203, from the plurality of clients, a plurality of model weight updates (see FIG. 9) prepared by each of the clients based on the initial neural network-based patterning model and a plurality of sets of local modeling data 209-1, 209-2, . . . , 209-M. The method further includes the server 203 aggregating the plurality of model weight updates to obtain a combined neural network-based patterning model 221, deploying the combined neural network-based patterning model, and refraining from communication between the clients and refraining from allowing any of the local modeling data to leave the clients (i.e., no local data leaves any clients and there is no communication between the clients).

It is worth noting that in one or more embodiments employing federated learning, privacy preservation is pertinent—for example, a cryptographic algorithm can encrypt the weight adjustments from different local models.

One or more embodiments further include repeating the steps of distributing, receiving, and aggregating using the combined neural network-based patterning model as the initial neural network-based patterning model, to obtain an updated combined neural network-based patterning model (see FIG. 10).

In one or more embodiments, each of the plurality of clients trains the initial neural network-based patterning model with the plurality of sets of local modeling data to obtain the plurality of model weight updates. With regard to local training, clients can share the same patterning process so they can share a model, but they can use their own masks, for example. That is, in one or more embodiments, everything is the same except the masks; masks of different designs are used to generate unique datasets.

In one or more embodiments, in the step of the server aggregating the plurality of model weight updates to obtain the combined neural network-based patterning model, a secure aggregation protocol using cryptographic techniques is employed to prevent the server from ascertaining which of the model weight updates are from which of the clients.

Patterning can be carried out with the combined neural network-based patterning model. For example, generate lithography masks based on the combined neural network-based patterning model, and then fabricate an integrated circuit using the lithography masks.

Referring briefly to FIG. 14, discussed in greater detail below, a “design house” can use EDA to carry out the processes depicted therein and then send the design 3121 to a fabricator/foundry who reworks the design for and generates the masks to fabricate the design, using techniques as disclosed herein.

The patterning models for either embodiments can, generally, include lithographic patterning models and/or etch patterning models.

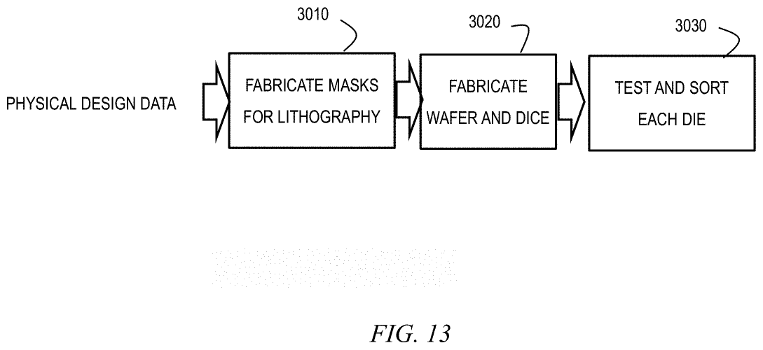

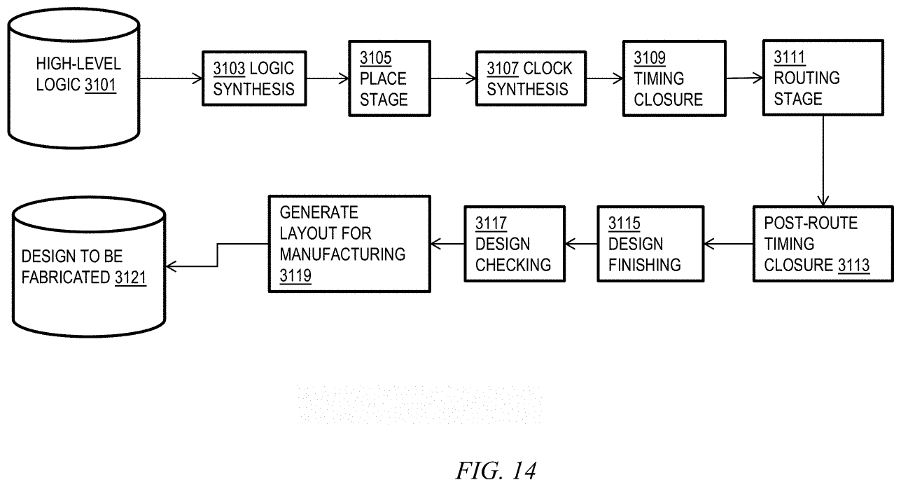

Once the model is obtained, based, in part, on the analytical processes described herein, an integrated circuit can be fabricated according to known processes that are generally described with reference to FIG. 13. Generally, a wafer with multiple copies of the final design is fabricated and cut (i.e., diced) such that each die is one copy of the integrated circuit. At block 3010, the processes include fabricating masks for lithography based on the models. At block 3020, fabricating the wafer includes using the masks to perform photolithography and etching. Once the wafer is diced, testing and sorting each die is performed at 3030 to filter out any faulty die.

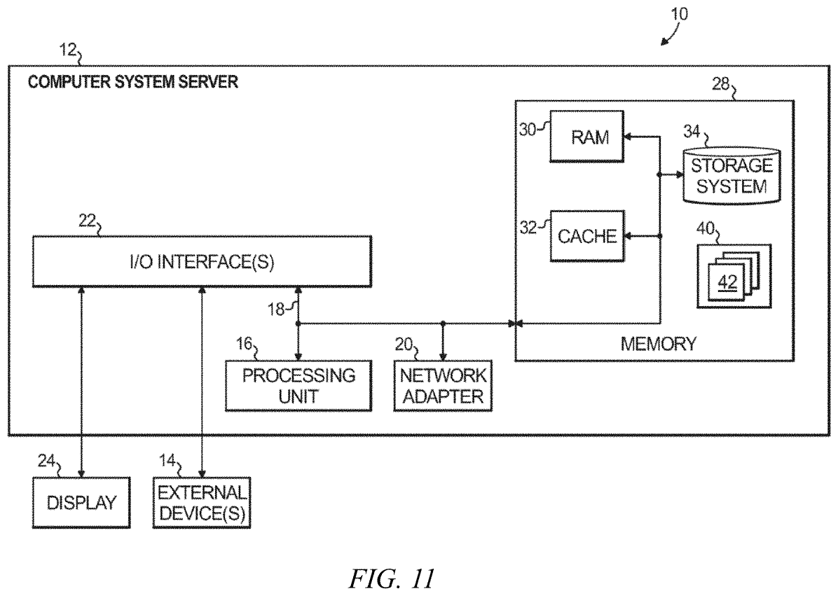

One or more embodiments include a computer including a memory 28; and at least one processor 16, coupled to the memory, and operative to carry out or otherwise facilitate any one, some, or all of the method steps described herein (as depicted in FIG. 11). In one or more embodiments, the performance (speed) of this computer is improved, for example, by reducing model update time and/or enhancing data security.

Furthermore, in one or more embodiments the at least one processor is operative to control lithography equipment (and possible other integrated circuit manufacturing equipment) to fabricate a physical integrated circuit in accordance with the model. The physical integrated circuit will be improved (for example, because of improved lithographic/etching processes).

FIG. 14 depicts an example high-level Electronic Design Automation (EDA) tool flow, which is responsible for creating an optimized microprocessor (or other IC) design to be manufactured. A designer could start with a high-level logic description 3101 of the circuit (e.g. VHDL or Verilog). The logic synthesis tool 3103 compiles the logic, and optimizes it without any sense of its physical representation, and with estimated timing information. The placement tool 3105 takes the logical description and places each component, looking to minimize congestion in each area of the design. The clock synthesis tool 3107 optimizes the clock tree network by cloning/balancing/buffering the latches or registers. The timing closure step 3109 performs a number of optimizations on the design, including buffering, wire tuning, and circuit repowering; its goal is to produce a design which is routable, without timing violations, and without excess power consumption. The routing stage 3111 takes the placed/optimized design, and determines how to create wires to connect all of the components, without causing manufacturing violations. Post-route timing closure 3113 performs another set of optimizations to resolve any violations that are remaining after the routing. Design finishing 3115 then adds extra metal shapes to the netlist, to conform with manufacturing requirements. The checking steps 3117 analyze whether the design is violating any requirements such as manufacturing, timing, power, electromigration (e.g., using techniques disclosed herein) or noise. When the design is clean, the final step 3119 is to generate a layout for the design, representing all the shapes to be fabricated in the design to be fabricated 3121.

One or more embodiments of the invention, or elements thereof, can be implemented in the form of an apparatus including a memory and at least one processor that is coupled to the memory and operative to perform exemplary method steps. FIG. 11 depicts a computer system that may be useful in implementing one or more aspects and/or elements of the invention; it is referred to herein as a cloud computing node but is also representative of a server, general purpose-computer, etc. which may be provided in a cloud or locally.

In cloud computing node 10 there is a computer system/server 12, which is operational with numerous other general purpose or special purpose computing system environments or configurations. Examples of well-known computing systems, environments, and/or configurations that may be suitable for use with computer system/server 12 include, but are not limited to, personal computer systems, server computer systems, thin clients, thick clients, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system/server 12 may be described in the general context of computer system executable instructions, such as program modules, being executed by a computer system. Generally, program modules may include routines, programs, objects, components, logic, data structures, and so on that perform particular tasks or implement particular abstract data types. Computer system/server 12 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 11, computer system/server 12 in cloud computing node 10 is shown in the form of a general-purpose computing device. The components of computer system/server 12 may include, but are not limited to, one or more processors or processing units 16, a system memory 28, and a bus 18 that couples various system components including system memory 28 to processor 16.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus.

Computer system/server 12 typically includes a variety of computer system readable media. Such media may be any available media that is accessible by computer system/server 12, and it includes both volatile and non-volatile media, removable and non-removable media.

System memory 28 can include computer system readable media in the form of volatile memory, such as random access memory (RAM) 30 and/or cache memory 32. Computer system/server 12 may further include other removable/non-removable, volatile/non-volatile computer system storage media. By way of example only, storage system 34 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 18 by one or more data media interfaces. As will be further depicted and described below, memory 28 may include at least one program product having a set (e.g., at least one) of program modules that are configured to carry out the functions of embodiments of the invention.

Program/utility 40, having a set (at least one) of program modules 42, may be stored in memory 28 by way of example, and not limitation, as well as an operating system, one or more application programs, other program modules, and program data. Each of the operating system, one or more application programs, other program modules, and program data or some combination thereof, may include an implementation of a networking environment. Program modules 42 generally carry out the functions and/or methodologies of embodiments of the invention as described herein.

Computer system/server 12 may also communicate with one or more external devices 14 such as a keyboard, a pointing device, a display 24, etc.; one or more devices that enable a user to interact with computer system/server 12; and/or any devices (e.g., network card, modem, etc.) that enable computer system/server 12 to communicate with one or more other computing devices. Such communication can occur via Input/Output (I/O) interfaces 22. Still yet, computer system/server 12 can communicate with one or more networks such as a local area network (LAN), a general wide area network (WAN), and/or a public network (e.g., the Internet) via network adapter 20. As depicted, network adapter 20 communicates with the other components of computer system/server 12 via bus 18. It should be understood that although not shown, other hardware and/or software components could be used in conjunction with computer system/server 12. Examples, include, but are not limited to: microcode, device drivers, redundant processing units, and external disk drive arrays, RAID systems, tape drives, and data archival storage systems, etc.

An interface to lithography machinery can be provided (e.g., 22 or 20), external devises 14 could include such machinery. the interface is coupled to the at least one processor, and the at least one processor is operative to send signals to the lithography machinery over the interface to cause the lithography machinery to generate lithography masks based on the updated neural network-based patterning model.

Thus, one or more embodiments can make use of software running on a general purpose computer or workstation. With reference to FIG. 11, such an implementation might employ, for example, a processor 16, a memory 28, and an input/output interface 22 to a display 24 and external device(s) 14 such as a keyboard, a pointing device, or the like. The term “processor” as used herein is intended to include any processing device, such as, for example, one that includes a CPU (central processing unit) and/or other forms of processing circuitry. Further, the term “processor” may refer to more than one individual processor. The term “memory” is intended to include memory associated with a processor or CPU, such as, for example, RAM (random access memory) 30, ROM (read only memory), a fixed memory device (for example, hard drive 34), a removable memory device (for example, diskette), a flash memory and the like. In addition, the phrase “input/output interface” as used herein, is intended to contemplate an interface to, for example, one or more mechanisms for inputting data to the processing unit (for example, mouse), and one or more mechanisms for providing results associated with the processing unit (for example, printer). The processor 16, memory 28, and input/output interface 22 can be interconnected, for example, via bus 18 as part of a data processing unit 12. Suitable interconnections, for example via bus 18, can also be provided to a network interface 20, such as a network card, which can be provided to interface with a computer network, and to a media interface, such as a diskette or CD-ROM drive, which can be provided to interface with suitable media.

Accordingly, computer software including instructions or code for performing the methodologies of the invention, as described herein, may be stored in one or more of the associated memory devices (for example, ROM, fixed or removable memory) and, when ready to be utilized, loaded in part or in whole (for example, into RAM) and implemented by a CPU. Such software could include, but is not limited to, firmware, resident software, microcode, and the like.

A data processing system suitable for storing and/or executing program code will include at least one processor 16 coupled directly or indirectly to memory elements 28 through a system bus 18. The memory elements can include local memory employed during actual implementation of the program code, bulk storage, and cache memories 32 which provide temporary storage of at least some program code in order to reduce the number of times code must be retrieved from bulk storage during implementation.

Input/output or I/O devices (including but not limited to keyboards, displays, pointing devices, and the like) can be coupled to the system either directly or through intervening I/O controllers.

Network adapters 20 may also be coupled to the system to enable the data processing system to become coupled to other data processing systems or remote printers or storage devices through intervening private or public networks. Modems, cable modem and Ethernet cards are just a few of the currently available types of network adapters.

As used herein, including the claims, a “server” includes a physical data processing system (for example, system 12 as shown in FIG. 11) running a server program. It will be understood that such a physical server may or may not include a display and keyboard.

It should be noted that any of the methods described herein can include an additional step of providing a system comprising distinct software modules embodied on a computer readable storage medium; the modules can include, for example, any or all of the appropriate elements depicted in the block diagrams and/or described herein; by way of example and not limitation, any one, some or all of the modules/blocks and or sub-modules/sub-blocks described. The method steps can then be carried out using the distinct software modules and/or sub-modules of the system, as described above, executing on one or more hardware processors such as 16. Further, a computer program product can include a computer-readable storage medium with code adapted to be implemented to carry out one or more method steps described herein, including the provision of the system with the distinct software modules.

One example of user interface that could be employed in some cases is hypertext markup language (HTML) code served out by a server or the like, to a browser of a computing device of a user. The HTML is parsed by the browser on the user's computing device to create a graphical user interface (GUI).

Exemplary System and Article of Manufacture Details

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Exemplary Design Process Used in Semiconductor Design, Manufacture, and/or Test

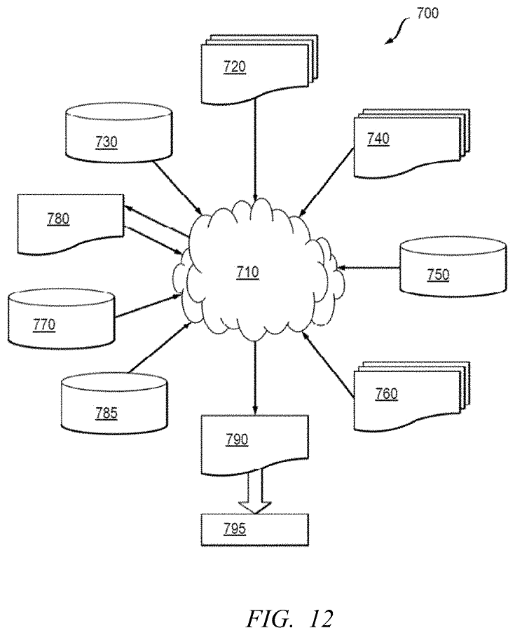

One or more embodiments integrate the characterizing and simulating techniques herein with semiconductor integrated circuit design simulation, test, layout, and/or manufacture. In this regard, FIG. 12 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 12 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc. Improved latch tree synthesis can be performed as described herein.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 790 may then proceed to a stage 795 where, for example, design structure 790: proceeds to tape-out, is released to manufacturing, is released to a mask house, is sent to another design house, is sent back to the customer, etc.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method for increasing the efficiency of electronic design automation, the method comprising:
employing a first subset of integrated circuit patterning modeling data to generate weights of a neural network-based patterning model;
employing a second subset of integrated circuit patterning modeling data to generate updated weights of said neural network-based patterning model, to obtain an updated neural network-based patterning model;
evaluating said updated neural network-based patterning model; and
responsive to said evaluating of said updated neural network-based patterning model being successfully completed, deploying said updated neural network-based patterning model.

2. The method of claim 1, further comprising generating lithography masks based on said updated neural network-based patterning model.

3. The method of claim 2, further comprising fabricating an integrated circuit using said lithography masks.

4. The method of claim 1, wherein said employing said second subset of said integrated circuit patterning modeling data to generate said updated weights of said neural network-based patterning model comprises using back-propagation.

5. The method of claim 4, further comprising segmenting a pre-existing dataset to obtain said first and second subsets.

6. The method of claim 4, further comprising collecting said first subset from a data stream at a first time and collecting said second subset from said data stream at a second time, later than said first time.

7. The method of claim 6, further comprising applying a larger learning rate to said second subset as compared to said first subset when generating said updated weights.

8. A method for increasing the efficiency of electronic design automation, the method comprising:
distributing an initial neural network-based patterning model from a server to a plurality of clients;
receiving, at said server, from said plurality of clients, a plurality of model weight updates prepared by each of said clients based on said initial neural network-based patterning model and a plurality of sets of local modeling data;
said server aggregating said plurality of model weight updates to obtain a combined neural network-based patterning model;
deploying said combined neural network-based patterning model; and
refraining from communication between said clients and refraining from allowing any of said local modeling data to leave said clients.

9. The method of claim 8, further comprising repeating said steps of distributing, receiving, and aggregating using said combined neural network-based patterning model as said initial neural network-based patterning model, to obtain an updated combined neural network-based patterning model.

10. The method of claim 9, further comprising each of said plurality of clients training said initial neural network-based patterning model with said plurality of sets of local modeling data to obtain said plurality of model weight updates.

11. The method of claim 8, wherein, in said step of said server aggregating said plurality of model weight updates to obtain said combined neural network-based patterning model, a secure aggregation protocol using cryptographic techniques is employed to prevent said server from ascertaining which of said model weight updates are from which of said clients.

12. The method of claim 8, further comprising generating lithography masks based on said combined neural network-based patterning model.

13. The method of claim 12, further comprising fabricating an integrated circuit using said lithography masks.

14. A computer comprising:
a memory; and
at least one processor, coupled to said memory, and operative to increase the efficiency of electronic design automation by:
employing a first subset of integrated circuit patterning modeling data to generate weights of a neural network-based patterning model;
employing a second subset of integrated circuit patterning modeling data to generate updated weights of said neural network-based patterning model, to obtain an updated neural network-based patterning model;
evaluating said updated neural network-based patterning model; and
responsive to said evaluating of said updated neural network-based patterning model being successfully completed, deploying said updated neural network-based patterning model.

15. The computer of claim 14, further comprising an interface to lithography machinery, said interface being coupled to said at least one processor, wherein said at least one processor is operative to send signals to said lithography machinery over said interface to cause said lithography machinery to generate lithography masks based on said updated neural network-based patterning model.

16. The computer of claim 14, wherein said employing said second subset of said integrated circuit patterning modeling data to generate said updated weights of said neural network-based patterning model comprises using back-propagation.

17. The computer of claim 16, wherein said at least one processor is operative to segment a pre-existing dataset to obtain said first and second subsets.

18. The computer of claim 16, wherein said at least one processor is operative to collect said first subset from a data stream at a first time and collect said second subset from said data stream at a second time, later than said first time.

19. The computer of claim 18, wherein said at least one processor is operative to apply a larger learning rate to said second subset as compared to said first subset when generating said updated weights.

20. The computer of claim 14, wherein said updated neural network-based patterning model comprises one of a lithographic patterning model and an etch patterning model.
